(19) United States
(12) Patent Application Publication
(10) Pub. No.: US 2009/0166868 A1
(43) Pub. Date: Jul. 2, 2009

(54) Semiconductor devices including metal interconnections and methods of fabricating the same

(75) Inventors: Jong-Myeong Lee, Gyeonggi-do (KR); Gil-Heyun Choi, Seoul (KR); Jong-Won Hong, Gyeonggi-do (KR); Hyun Park, Gyeonggi-do (KR); Kyung-In Choi, Seoul (KR); Hyun-Bae Lee, Seoul (KR)

Correspondence Address: MYERS BIGEL SIBLEY & SAJOVEC, PO BOX 37428, RALEIGH, NC, 27627, US

(73) Assignee: Samsung Electronics, Co., Ltd.

(21) Appl. No.: 12/011,750

(22) Filed: Jan. 29, 2008

(30) Foreign Application Priority Data
Jan. 29, 2007 (KR) 10-2007-0009008

(51) Int. Cl. H01L 23/52; H01L 21/4763

(52) U.S. Cl. 257/751; 257/734; 438/622; 257/E21.496; 257/E23.141

(57) ABSTRACT

A semiconductor device includes a first interlayer dielectric including a trench on a semiconductor layer, a mask pattern on the first interlayer dielectric, a first conductive pattern in the trench, and a second interlayer dielectric on the mask pattern. The second interlayer dielectric includes an opening over the first conductive pattern. A second conductive pattern is in the opening and is electrically connected to the first conductive pattern. The first conductive pattern has an upper surface lower than an upper surface of the mask pattern.

### CROSS-REFERENCE TO RELATED APPLICATIONS

This U.S. non-provisional patent application claims priority under 35 U.S.C. § 119 to Korean Patent Application No. 10-2007-0009008, filed on Jan. 29, 2007, the disclosure of which is hereby incorporated by reference.

### BACKGROUND

The present invention relates to semiconductor devices and a methods of fabricating the same, and more particularly, to semiconductor devices including metal interconnections and methods of fabricating the same.

Semiconductor devices are becoming microminiaturized and ultra lightweight. To accomplish this, the integration degree of the semiconductor devices is being increased. As semiconductor devices become more highly integrated, the design rule decreases. As the design rule decreases, widths and thicknesses of metal interconnections gradually decrease. Accordingly, the resistance of the metal interconnections may greatly increase. In order to reduce the resistance of the metal interconnections, copper interconnections with low resistivity may be used. A damascene process may be performed to form the copper interconnections.

Semiconductor devices include various layers. Thus, alignment between the various layers may be very important. As the design rule decreases, the spacing between the metal interconnections is reduced, thereby causing a limitation in alignment of via contacts connecting upper metal interconnections and lower metal interconnections. Additionally, as the spacing between metal interconnections decreases, a time dependent dielectric breakdown (TDDB) phenomenon may have a direct effect on the lifetime of the semiconductor device. Therefore, the reliability of the semiconductor devices may be degraded due to the TDDB phenomenon.

### SUMMARY

Some embodiments provide semiconductor devices including a first interlayer dielectric including a trench on a semiconductor layer, a mask pattern on the first interlayer dielectric, a first conductive pattern in the trench, and a second interlayer dielectric on the mask pattern. The second interlayer dielectric includes an opening over the first conductive pattern. A second conductive pattern is in the opening and is electrically connected to the first conductive pattern. The first conductive pattern has an upper surface lower than an upper surface of the mask pattern.

In some embodiments, the first conductive pattern may have an etch selectivity with respect to the mask pattern. The first conductive pattern may include copper. The mask pattern may include a silicon nitride (SiN) layer, a silicon carbide (SiC) layer, and/or a silicon carbonitride (SiCN) layer. The mask pattern may have an etch selectivity with respect to the first interlayer dielectric. The first interlayer dielectric may include a silicon oxide (SiO₂) layer and/or a silicon oxycarbide (SiOC) layer. The mask pattern may have an etch selectivity with respect to the second interlayer dielectric, and the trench may pass through the mask pattern. The upper surface of the first conductive pattern may be higher than a lower surface of the mask pattern.

In other embodiments, the semiconductor devices may further include a diffusion barrier between the first conductive pattern and the second conductive pattern that may, for example, reduce/prevent diffusion of copper ions. The diffusion barrier may be selectively disposed on the first conductive pattern. The diffusion barrier may include a copper silicon nitride (CuSiN) layer.

The diffusion barrier may have an upper surface that is substantially coplanar with an upper surface of the mask pattern and/or that is lower than an upper surface of the mask pattern. The diffusion barrier may have a lower surface that is higher than a lower surface of the mask pattern.

The semiconductor layer may include a semiconductor substrate.

In other embodiments, methods for fabricating semiconductor devices include forming a first interlayer dielectric having a trench on a semiconductor layer, forming a mask pattern on the first interlayer dielectric, forming a planarized first conductive interconnection pattern filling the trench, recessing the first conductive interconnection pattern to form a first conductive pattern, forming a second interlayer dielectric on the mask pattern, the second interlayer dielectric including an opening over the first conductive pattern, and forming a second conductive pattern in the opening and connected to the first conductive pattern.

In some embodiments, the recessing of the first conductive interconnection pattern may include a performing chemical mechanical polishing (CMP) process. The first conductive interconnection pattern may have an etch selectivity with respect to the mask pattern.

In other embodiments, the forming of the first interlayer dielectric and the mask pattern may include forming the first interlayer dielectric on the semiconductor substrate, forming a mask layer on the first interlayer dielectric, and patterning the mask layer and the first interlayer dielectric to form the trench. The mask layer may have an etch selectivity with respect to the first interlayer dielectric. The mask layer may include a silicon nitride (SiN) layer, a silicon carbide (SiC) layer, and/or a silicon carbonitride (SiCN) layer. The first interlayer dielectric may include a silicon oxide (SiO₂) layer and/or a silicon oxycarbide (SiOC) layer.

In still other embodiments, the mask pattern may have an etch selectivity with respect to the second interlayer dielectric, and the trench passes through the mask pattern. The mask pattern may include a silicon nitride (SiN) layer, a silicon carbide (SiC) layer, and/or a silicon carbonitride (SiCN) layer. The second interlayer dielectric may include a silicon oxide (SiO₂) layer and/or a silicon oxycarbide (SiOC) layer.

In some embodiments, the methods may further include forming a diffusion barrier on the first conductive pattern. The diffusion barrier may be selectively formed by an electroless plating process and/or a plasma self aligned barrier process.

The diffusion barrier may have an upper surface that is substantially coplanar with an upper surface of the mask pattern and/or that is lower than an upper surface of the mask pattern. The diffusion barrier may have a lower surface that is higher than a lower surface of the mask pattern.

The semiconductor layer may include a semiconductor substrate.

Methods of fabricating a semiconductor device according to further embodiments include forming a first interlayer dielectric having a trench on a semiconductor layer, forming a mask pattern on the first interlayer dielectric, forming a first conductive interconnection pattern in the trench, and recessing the first conductive interconnection pattern to form a first conductive pattern. The first conductive interconnection pattern may be recessed using a chemical mechanical polishing (CMP) process so that the first conductive pattern may have an upper surface that is lower than an upper surface of the mask pattern. The methods further include forming a diffusion barrier on the first conductive pattern, forming a second interlayer dielectric on the mask pattern, the second interlayer dielectric including an opening exposing the diffusion barrier, and forming a second conductive pattern in the opening on the diffusion barrier.

The diffusion barrier may be selectively formed by an electroless plating process to have an upper surface that is substantially coplanar with an upper surface of the mask pattern.

In some embodiments, the diffusion barrier may be formed by a plasma self aligned barrier process to have an upper surface that is lower than an upper surface of the mask pattern.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1 is a cross-sectional view of a semiconductor device according to some embodiments;

FIGS. 2A through 2E are cross-sectional views illustrating methods of fabricating the semiconductor device according to some embodiments;

FIG. 3 is a cross-sectional view of a semiconductor device according to further embodiments;

FIGS. 4A through 4C are cross-sectional views illustrating methods of fabricating the semiconductor device according to further embodiments;

FIG. 5 is a cross-sectional view of a semiconductor device according to further embodiments;

FIGS. 6A through 6B are cross-sectional views illustrating a method of fabricating the semiconductor device according to further embodiments; and

FIGS. 7A and 7B are cross-sectional views illustrating methods of fabricating a semiconductor device according to further embodiments.

### DETAILED DESCRIPTION

Embodiments now will be described more fully hereinafter with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “over” or “under” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

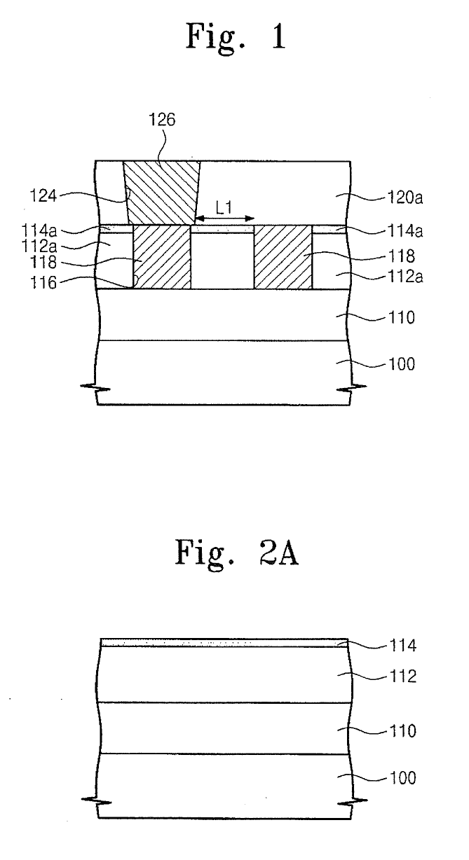

FIG. 1 is a cross-sectional view of a semiconductor device according to some embodiments.

A first interlayer dielectric (ILD) 110 is disposed on a semiconductor substrate 100. The first ILD 110 may be a silicon oxide (SiO₂) layer. The first ILD 11O may include a conductor (not shown) thereon. The conductor may include a contact plug electrically connected to a drain region (not shown) defined on the semiconductor substrate 100. A second ILD 112a is disposed on the first ILD 110, and a mask pattern 114a is disposed on the second ILD 112a. The second ILD 112a and the mask pattern 114a include a trench 116. The trench 116 may pass through the mask pattern 114a. The mask pattern 114a may have an etch selectivity with respect to the second ILD 112a. The mask pattern 114a may include a silicon nitride (SiN) layer, a silicon carbide (SiC) layer, and/or a silicon carbonitride (SiCN) layer. The second ILD 112a may include a silicon oxide (SiO₂) layer and/or a silicon oxycarbide (SiOC) layer.

A first conductive pattern 118 is filled in the trench 116. The first conductive pattern 118 may be a metal interconnection. The metal interconnection may be a copper interconnection. The copper interconnection may be a bit line. A third ILD 120a having an opening 124, which exposes the first conductive pattern 118, is disposed on the mask pattern 114a. The opening 124 may be a via hole. The mask pattern 114a may have an etch selectivity with respect to the third ILD 120a. The mask pattern 114a may include a SiN layer, a SiC layer, and/or a SiCN layer. The third ILD 120a may include a SiO₂ layer and/or a SiOC layer. In particular embodiments, the mask pattern 114a and the third ILD 120a may be SiN and SiO₂, respectively.

A second conductive pattern 126 is filled in the opening 124 and is connected to the first conductive pattern 118. The second conductive pattern 126 may be a via contact. The via contact may include tungsten (W), polysilicon, titanium nitride (TiN), tungsten nitride (WN), and/or copper (Cu). A space between a lower edge of the second conductive pattern 126 and an upper edge of the first conductive patten 118 adjacent to the second conductive pattern 126 is indicated as L1.

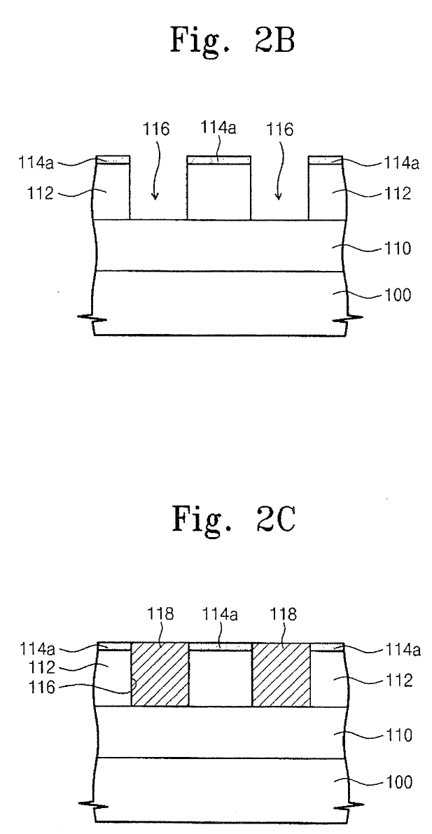

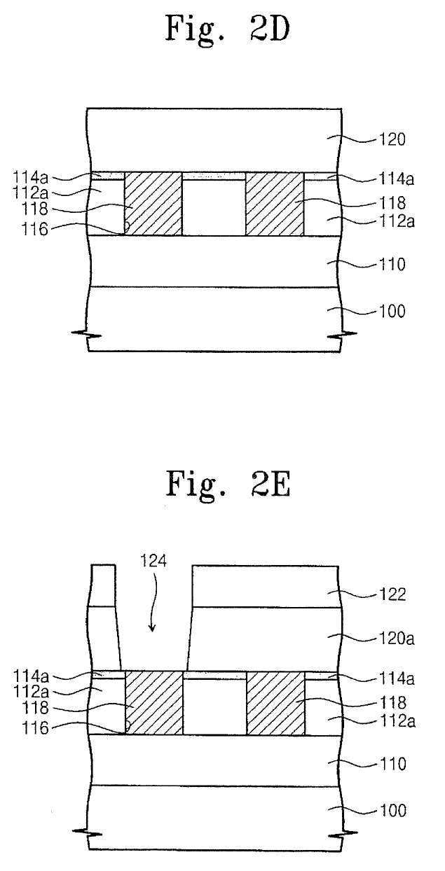

FIGS. 2A through 2E are cross-sectional views illustrating methods of fabricating semiconductor devices according to some embodiments.

Referring to FIG. 2A, a first ILD 110 may be formed on a semiconductor substrate 100. The first ILD 110 may be a SiO₂ layer. The first ILD 110 may include a conductor (not shown) formed on the semiconductor substrate 100. The conductor may include a contact plug electrically connected to a drain region (not shown) defined on the semiconductor substrate 100. An etch stop layer (not shown) may be formed on the first ILD 110.

A second ILD 112 is formed on the first ILD 110. The second ILD 112 may be a SiO₂ layer. A mask layer 114 is formed on the second ILD 112. The mask layer 114 may have an etch selectivity with respect to the second ILD 112. The mask layer 114 may include a SiN layer, a SiC layer, and/or a SiCN layer. The mask layer 114 may serve as an etch stop layer.

Referring to FIG. 2B, the mask layer 114 and the second ILD 112 are patterned to form a trench 116 exposing the first ILD 110.

Referring to FIG. 2C, a first conductive layer is formed on the mask pattern 114a to fill the trench 116. The first conductive layer may include a barrier layer that prevents/opposes movement of copper, a seed layer for growth of the copper, and a copper layer that is grown from the seed layer. The first conductive layer is planarized until the mask pattern 114a is exposed to form a first conductive pattern 118. The planarization process may be performed using, for example, a chemical mechanical polishing (CMP) process. The first conductive pattern 118 may be a metal interconnection. The metal interconnection may be a copper interconnection. The copper interconnection may be a bit line.

Referring to FIG. 2D, a third ILD 120 is formed on the first conductive pattern 118 and the mask pattern 114a. The third ILD 120 may have an etch selectivity with respect to the mask pattern 114a. The third ILD 120 may include a SiO₂ layer and/or a SiOC layer.

Referring to FIG. 2E, a photoresist pattern 122 is formed on the third ILD 120. The third ILD 120 is etched until the first conductive pattern 118 is exposed using the photoresist pattern 122 as an etch mask, thereby forming an opening 124. The opening 124 may be a via hole. The photoresist pattern 122 is removed using, for example, an ashing process.

Again referring to FIG. 1, a second conductive layer is formed on a third ILD 120a to fill the opening 124. The second conductive layer may be formed of W, polysilicon, TiN, and/or WN. The second conductive layer is planarized to form a second conductive pattern 126 connected to the first conductive pattern 118. The second conductive pattern 126 may be a via contact. A space between a lower edge of the second conductive pattern 126 and an upper edge of the first conductive pattern 118 adjacent to the second conductive pattern 126 is indicated as L1.

FIG. 3 is a cross-sectional view of a semiconductor device according to further embodiments.

Referring to FIG. 3, a first ILD 110 is disposed on a semiconductor substrate 100. The first ILD 10 may be a SiO₂ layer. The first ILD 110 may include a conductor (not shown). The conductor may include a contact plug electrically connected to a drain region (not shown) defined on the semiconductor substrate 100. A second ILD 112a is disposed on the first ILD 110, and a mask pattern 114a is disposed on the second ILD 112a. The second ILD 112a and the mask pattern 114a include a trench 116. The mask pattern 114a may have an etch selectivity with respect to the second ILD 112a. The mask pattern 114a may include a SiN layer, a SiC layer, and/or a SiCN layer. The second ILD 112a may include a SiO₂ layer and/or a SiOC layer.

A first conductive pattern 118a having an upper surface lower than an upper surface of the mask pattern 114a is disposed in the trench 116. The upper surface of the first conductive pattern 118a may be higher than a lower surface of the mask pattern 114a. The first conductive pattern 11 8a may have a chemical mechanical polish (CMP) selectivity with respect to the mask pattern 114a. The first conductive pattern 118a may include copper. The first conductive pattern 118a may be a metal interconnection. The metal interconnection may be a copper interconnection. The copper interconnection may be a bit line.

A diffusion barrier 119 for reducing/preventing diffusion of copper ions is disposed on the first conductive pattern 118a. The diffusion barrier 119 may be a conductive layer. The diffusion barrier 119 may be selectively disposed on the first conductive pattern 118a. The diffusion barrier 119 may include a cobalt (Co) layer, a nickel (Ni) layer, and/or a palladium (Pd) layer. The diffusion barrier 119 has an upper surface that is substantially coplanar with an upper surface of the mask pattern 114a. The lower surface of the diffusion barrier 119 may be higher than the lower surface of the mask pattern 114a.

A third ILD 120a, having an opening 124 (similar to 124 of FIG. 2E) that is over the first conductive pattern 118a and that exposes the diffusion barrier 119, is disposed on the mask pattern 114a. The opening 124 may be a via hole. The mask pattern 114a may have the etch selectivity with respect to the third ILD 120a. The third TLD 120a may include a SiO₂ layer and/or a SiOC layer.

A second conductive pattern 126a is disposed on the diffusion barrier 119 and may fill the opening 124. The second conductive pattern 126a may be electrically connected to the diffusion barrier 119 and the first conductive pattern 118a. The second conductive pattern 126a may be a via contact. The via contact may be formed of W, polysilicon, TiN, WN, and/or Cu.

A space between a lower edge of the second conductive pattern 126a and an upper edge of the first conductive pattern 118a adjacent to the second conductive pattern 126a is indicated as L4.

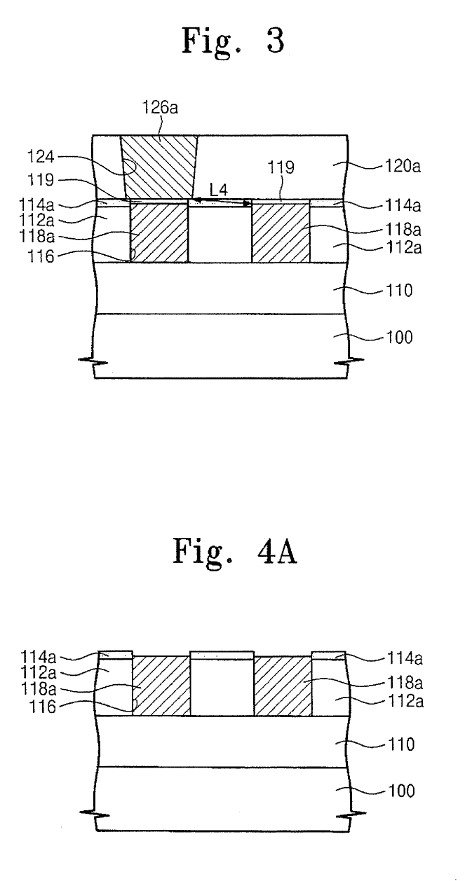

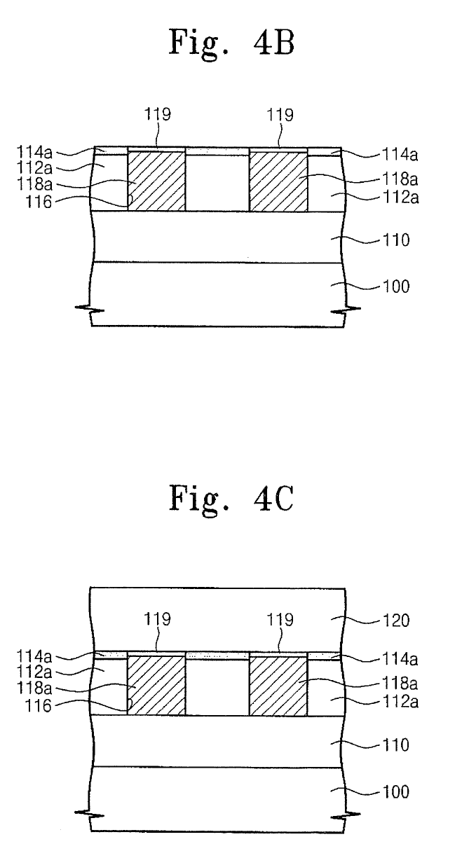

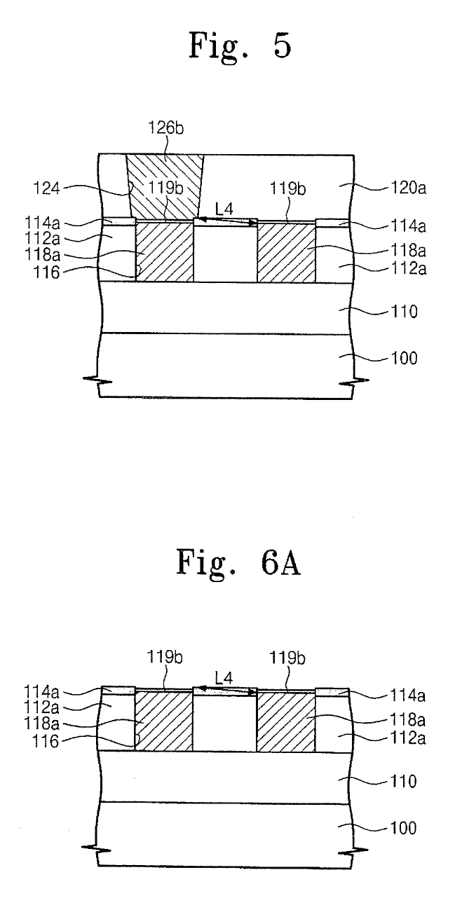

FIGS. 4A through 4C are cross-sectional views illustrating methods of fabricating semiconductor devices according to further embodiments.

Referring to FIG. 4A, a first conductive pattern 118 of FIG. 2C is recessed to form a first conductive interconnection pattern 118a. The recess process may be performed using, for example, a CMP process. The first conductive pattern 118 may have a CMP selectivity with respect to the mask pattern 114a. As a result, a first conductive interconnection pattern 11 8a may have a top surface lower than a top surface of the mask pattern 114a. The first conductive interconnection pattern 118a may be a metal interconnection. The metal interconnection may be a copper interconnection. The copper interconnection may be a bit line.

Referring to FIG. 4B, a diffusion barrier 119 may be formed on the first conductive interconnection pattern 118a. The diffusion barrier 119 may be formed, for example, by an electroless plating process. The electroless plating process may be performed to selectively form the diffusion barrier 119 on the first conductive interconnection pattern 118a. The diffusion barrier 119 may include a Co layer, a Ni layer, and/or a Pd layer. A thickness of the diffusion barrier 119 may be about 100 Å. The diffusion barrier 119 may reduce/prevent copper from diffusing from the copper interconnection into a third ILD toward a via contact adjacent to the copper interconnection that is formed through a subsequent process.

Referring to FIG. 4C, the third ILD 120 is formed on the diffusion barrier 119 and the mask pattern 114a. In some embodiments, the third ILD 120 may have a dry etch selectivity with respect to the mask pattern 114a. The third ILD 120 may include a SiO₂ layer and/or a SiOC layer.

Again referring to FIG. 3, a photoresist pattern (not shown) may be formed on the third ILD 120. The photoresist pattern may be patterned to form a mask pattern (not shown). The third ILD 120 is etched until the diffusion barrier 119 is exposed using the mask pattern as an etch mask, thus forming a third ILD 120a having an opening 124.

A second conductive layer is formed on the third ILD 120a to fill the opening 124. The second conductive layer may be formed of W, polysilicon, TiN, and/or WN. The second conductive layer is planarized to form the diffusion barrier 119 and a second conductive pattern 126a electrically connected to the first conductive interconnection pattern 118a. The second conductive pattern 126a may be a via contact. A space between a lower edge of the second conductive pattern 126a and an upper edge of the first conductive pattern 118a adjacent to the second conductive pattern 126a is indicated as L4.

Unlike some embodiments, the first conductive interconnection pattern 118a may have a top surface lower than a top surface of the mask pattern 114a. That is, the space L4 (see FIG. 3) may be greater than the space LI illustrated in FIG. 1. The space L4 may be extended according to the recessed depth. As a result, a time dependent dielectric breakdown (TDDB) phenomenon can be reduced even more.

FIG. 5 is a cross-sectional view of a semiconductor device according to further embodiments.

Referring to FIG. 5, a first ILD 110 is disposed on a semiconductor substrate 100. The first ILD 110 may be a SiO₂ layer. The first ILD 110 may include a conductor (not shown). The conductor may include a contact plug electrically connected to a drain region (not shown) defined on the semiconductor substrate 100. A second ILD 112a is disposed on the first ILD 110, and a mask pattern 114a is disposed on the second ILD 112a. The second ILD 112a and the mask pattern 114a include a trench 116. The mask pattern 114a may have an etch selectivity with respect to the second ILD 112a. The mask pattern 114a may include a SiN layer, a SiC layer, and/or a SiCN layer. The second ILD 112a may include a SiO₂ layer and/or a SiOC layer.

A first conductive pattern 118a having a top surface lower than a top surface of the mask pattern 114a is disposed in the trench 116. The first conductive pattern 118a may be a metal interconnection. The metal interconnection may be a copper interconnection. The copper interconnection may be a bit line. The first conductive pattern 118a may have an etch selectivity with respect to the mask pattern 114a. The first conductive pattern 118a may include copper.

A diffusion barrier 119b that reduces/prevents diffusion of copper ions is disposed on the first conductive pattern 118a. The diffusion barrier 119b may be a conductive layer. The diffusion barrier 119b may be a copper silicon nitride (CuSiN) layer. The diffusion barrier 119b may have an upper surface that is lower than an upper surface of the mask pattern 114a. In addition, the lower surface of the diffusion barrier 119b may be higher than the lower surface of the mask pattern 114a.

A third ILD 120a having the opening (see 124 of FIG. 2E), which exposes the diffusion barrier 119b, is disposed on the mask pattern 114a. The opening 124 may be a via hole. The mask pattern 114a may have the etch selectivity with respect to the third ILD 120a. The third ILD 120a may include a SiO₂ layer and/or a SiOC layer.

A second conductive pattern 126b is filled in the opening 124 and is electrically connected to the diffusion barrier 119b and the first conductive pattern 118a. The second conductive pattern 126b may be a via contact. The via contact may be formed of W, polysilicon, TiN, WN, and/or Cu.

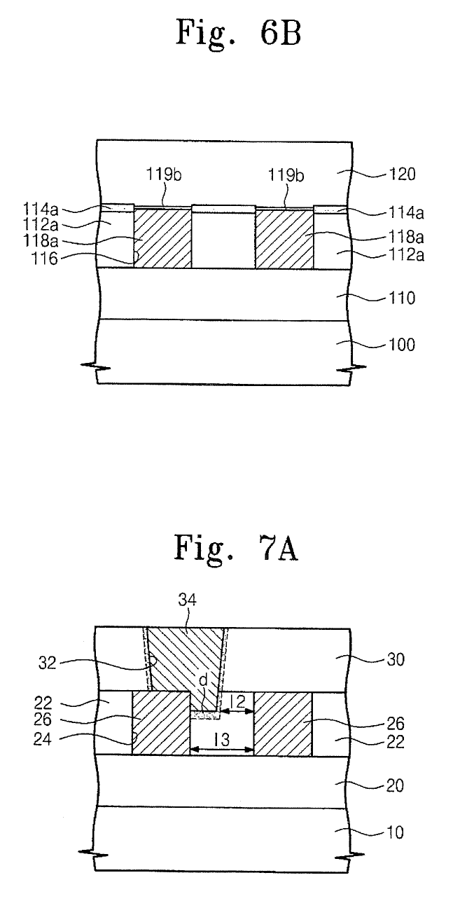

FIGS. 6A through 6B are cross-sectional views illustrating methods of fabricating a semiconductor device according to further embodiments.

Referring to FIG. 6A, a diffusion barrier 119b may be selectively formed on a conductive interconnection pattern 118a of FIG. 4A. The diffusion barrier 119b may be formed, for example, by a plasma self aligned barrier process. Silane (SiH4) and ammonia (NH3) are used as reaction gas in the plasma self aligned barrier process. The diffusion barrier 119b may be a CuSiN layer. A thickness of the diffusion barrier 119b may be in the range of about 10˜20 Å. The diffusion barrier 119b may reduce/prevent diffusion of copper ions from a copper interconnection into a third ILD toward a via contact adjacent to the copper interconnection that is formed through a subsequent process.

Referring to FIG. 6B, a third ILD 120 is formed on the diffusion barrier 119b and the mask pattern 114a. The third ILD 120 may have a dry etch selectivity with respect to the mask pattern 114a. The third ILD 120 may include a SiO₂ layer and/or a SiOC layer.

Again referring to FIG. 5, a photoresist pattern (not shown) may be formed on the third ILD 120. The photoresist pattern may be patterned to form a mask pattern. The third ILD 120 is etched until the diffusion barrier 119b is exposed using the mask pattern as an etch mask, thereby forming a third ILD 120a having an opening 124.

A second conductive layer is formed on the third ILD 120a to fill the opening 124. The second conductive layer may be formed of W, polysilicon, TiN, and/or WN. The second conductive layer is planarized to form a second conductive pattern 126b that is electrically connected to the first conductive interconnection pattern 118a. The second conductive pattern 126b may be a via contact.

Unlike some embodiments, the first conductive interconnection pattern 118a may have a top surface lower than a top surface of the mask pattern 114a. That is, the space L4 may be greater than the space LI illustrated in FIG. 1. Accordingly, the space L4 may be extended according to the recessed depth. As a result, a time dependent dielectric breakdown (TDDB) phenomenon can be reduced.

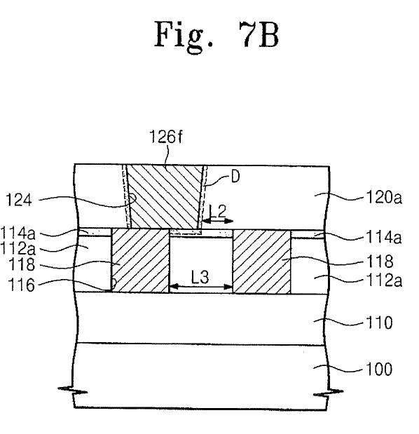

FIGS. 7A and 7B are cross-sectional views illustrating methods of fabricating a semiconductor device according to still further embodiments.

FIG. 7A is a cross-sectional view of a semiconductor device in a case where a via contact is misaligned when a mask pattern does not exist. FIG. 7B is a cross-sectional view of a semiconductor device in a case where a via contact is misaligned when a mask pattern exists.

Referring to FIG. 7A, a first ILD 20 is disposed on a semiconductor substrate 10. The first ILD 20 may be a SiO₂ layer. A second ILD 22 is disposed on the first ILD 20. The second ILD 22 includes a trench 24. The second ILD 22 may be a SiO₂ layer.

A first conductive pattern 26 is filled in the trench 24. The first conductive pattern 26 may be a metal interconnection. The metal interconnection may be a copper interconnection. A third ILD 30 having an opening 32, which exposes the first conductive pattern 26 is disposed on the second ILD 22. The opening 32 may be a via hole. The third ILD 30 may be SiO₂.

A second conductive pattern 34 is filled in the opening 32 and is electrically connected to the first conductive pattern 26. The second conductive pattern 34 may be a via contact.

Misalignment may occur in an arrangement of the opening 32. Hence, in an etch process for forming the opening 32, the second ILD 22 adjacent to the first conductive pattern 26 may be over-etched due to the misalignment of the opening 32. A second conductive pattern 34 is disposed on the first conductive pattern 26 including the over-etched portion.

A lower portion of the second conductive pattern 34 is disposed between the first conductive patterns 26. Since the lower portion of the second conductive pattern 34 is additionally disposed between the first conductive patterns 26, a TDDB phenomenon can increase.

A space between the first conductive patterns may be indicated as 13. A space between a lower edge of the second conductive pattern 34 and an upper edge of the first conductive pattern 26 adjacent to the second conductive pattern 34 may be indicated as 12. The space 12 may be less than the space 13. That is, the TDDB phenomenon may become more serious in the case of the space 12. In addition, damage due to the over-etching may occur in the etch process for forming the opening 32. Hatched regions around the via contact may indicate an etch damaged portion d. An inner defect due to the damage may exist between the first conductive patterns 26. The inner defect may include a dislocation. As a result, the TDDB phenomenon can increase even more.

Referring to FIG. 7B, in cases where a metal interconnection is disposed according to some embodiments, misalignment may occur in an arrangement of an opening 124 during the formation of a photoresist pattern 122 of FIG. 2E. In an etch process for forming the opening 124, since a mask pattern 114a may have an etch selectivity with respect to a third ILD 120a, the mask pattern 114a may be used as an etch stop layer. Hence, in case of the misalignment of the opening 124, a second conductive pattern 126f may be disposed on the mask pattern 114a. That is, since the second conductive pattern 126f does not exist between first conductive patterns 116, a TDDB phenomenon can be reduced.

In addition, a second ILD 112a adjacent to an upper portion of the first conductive pattern 116 is not over-etched. Hatched regions around the second conductive pattern 126f may indicate an etch damaged portion D. A space between the first conductive patterns 116 may be indicated as L3. A space between a lower edge of the second conductive pattern 126f and the first conductive pattern 116 adjacent to the second conductive pattern 126f may be indicated as L2.

Since the over-etching may not occur, the etch damaged portion D of FIG. 7B may be less than the etch damaged portion d of FIG. 7A. Accordingly, the etch damaged portion D corresponding to an over-etching depth may be reduced. As a result, the TDDB phenomenon can be reduced even more.

As described above, according to some embodiments , the generation of the TDDB phenomenon can be reduced even though a via contact is misaligned. Therefore, the reliability of the semiconductor devices can be improved.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A semiconductor device, comprising:
a semiconductor layer,
a first interlayer dielectric including a trench on the semiconductor layer;
a mask pattern on the first interlayer dielectric;
a first conductive pattern in the trench;
a second interlayer dielectric on the mask pattern, the second interlayer dielectric including an opening over the first conductive pattern; and
a second conductive pattern in the opening and electrically connected to the first conductive pattern,
wherein the first conductive pattern has an upper surface lower than an upper surface of the mask pattern.

2. The semiconductor device of claim 1, wherein the upper surface of the first conductive pattern is higher than a lower surface of the mask pattern.

3. The semiconductor device of claim 1, further comprising a diffusion barrier between the first conductive pattern and the second conductive pattern.

4. The semiconductor device of claim 3, wherein the diffusion barrier has an upper surface that is substantially coplanar with an upper surface of the mask pattern.

5. The semiconductor device of claim 3, wherein the diffusion barrier has an upper surface that is lower than an upper surface of the mask patten.

6. The semiconductor device of claim 3, wherein the diffusion barrier has a lower surface that is higher than a lower surface of the mask pattern.

7. The semiconductor device of claim 3, wherein the diffusion barrier is configured to reduce diffusion of copper atoms.

8. The semiconductor device of claim 7, wherein the diffusion barrier comprises a copper silicon nitride (CuSiN) layer.

9. A method for fabricating a semiconductor device, the method comprising:
forming a first interlayer dielectric having a trench on a semiconductor layer;
forming a mask pattern on the first interlayer dielectric;
forming a first conductive interconnection pattern in the trench;
recessing the first conductive interconnection pattern to form a first conductive pattern;
forming a second interlayer dielectric on the mask pattern, the second interlayer dielectric including an opening over the first conductive pattern; and
forming a second conductive pattern in the opening and electrically connected to the first conductive pattern.

10. The method of claim 9, wherein the recessing of the first conductive interconnection pattern comprises performing a chemical mechanical polishing (CMP) process.

11. The method of claim 9, wherein the first conductive interconnection pattern has an etch selectivity with respect to the mask pattern.

12. The method of claim 9, further comprising forming a diffusion barrier on the first conductive pattern, wherein the diffusion barrier is between the first conductive pattern and the second conductive pattern.

13. The method of claim 12, wherein the diffusion barrier is selectively formed by an electroless plating process.

14. The method of claim 12, wherein the diffusion barrier is formed by a plasma self aligned barrier process.

15. The method of claim 12, wherein the diffusion barrier has an upper surface that is substantially coplanar with an upper surface of the mask pattern.

16. The method of claim 12, wherein the diffusion barrier has an upper surface that is lower than an upper surface of the mask pattern.

17. The method of claim 12, wherein the diffusion barrier has a lower surface that is higher than a lower surface of the mask pattern.

18. A method for fabricating a semiconductor device, the method comprising:
forming a first interlayer dielectric having a trench on a semiconductor layer;
forming a mask pattern on the first interlayer dielectric;
forming a first conductive interconnection pattern in the trench;
recessing the first conductive interconnection pattern to form a first conductive pattern using a chemical mechanical polishing (CMP) process so that the first conductive pattern has an upper surface that is lower than an upper surface of the mask pattern;
forming a diffusion barrier on the first conductive pattern;
forming a second interlayer dielectric on the mask pattern, the second interlayer dielectric including an opening exposing the diffusion barrier; and
forming a second conductive pattern in the opening on the diffusion barrier.

19. The method of claim 18, wherein the diffusion barrier is selectively formed by an electroless plating process to have an upper surface that is substantially coplanar with an upper surface of the mask pattern.

20. The method of claim 18, wherein the diffusion barrier is formed by a plasma self aligned barrier process to have an upper surface that is lower than an upper surface of the mask pattern.
